(19) United States
(12) Patent Application Publication
(10) Pub. No.: US 2025/0113701 A1
(43) Pub. Date: Apr. 3, 2025

(54) OPTOELECTRONIC DEVICE

(71) Applicant: STMicroelectronics International N.V., Geneva (CH)

(72) Inventor: Arthur ARNAUD, La Tronche (FR)

(73) Assignee: STMicroelectronics International N.V., Geneva (CH)

(21) Appl. No.: 18/894,519

(22) Filed: Sep. 24, 2024

(30) Foreign Application Priority Data
Sep. 29, 2023 (FR) 2310461

(51) Int. Cl. H10K 39/00; H10K 39/32

(52) U.S. Cl. CPC H10K 39/621; H10K 39/32

(57) ABSTRACT

A device includes an assembly of pixels with a first pixel generating an event-based data element and a second pixel generating a light intensity data element. Each first and second pixel includes a portion of a layer that forms a photodiode. A first integrated circuit chip includes a first substrate and a first interconnection network, and a second integrated circuit chip includes a second substrate and a second interconnection network. The first and second integrated circuit chips are attached to each other by the first and second interconnection networks. The layer with the photodiodes is located on a first surface of the second substrate opposite to a second surface of the second substrate having the second interconnection network located thereon.

### PRIORITY CLAIM

This application claims the priority benefit of French Application for Patent No. 2310461, filed on Sep. 29, 2023, the content of which is hereby incorporated by reference in its entirety to the maximum extent allowable by law.

### TECHNICAL FIELD

The present disclosure generally concerns electronic devices and, more specifically, optoelectronic devices.

### BACKGROUND

Event-based cameras, like standard cameras, comprise a plurality of pixels, each pixel being configured to deliver a value corresponding to a location in an observed scene. However, conversely to a standard camera, that is, a camera having each of its pixel configured to periodically deliver a light intensity value corresponding to the location, an event-based camera is configured to deliver information indicating a modification of the light intensity. Event-based cameras are thus configured to deliver an event-based image of a scene. Standard cameras are thus configured to deliver a light intensity image of a scene. Thus, a standard camera is a synchronous camera enabling to obtain at a frame frequency a succession of images comprising as many intensity values as pixels. An event-based camera is a synchronous or asynchronous camera providing, for each pixel, information indicating the change of brightness of the corresponding location in the scene. When the scene is still, a standard camera keeps on delivering, periodically, all the intensity values, while an event-based camera delivers no value, indicating the lack of change.

There is a need in the art to overcomes all or part of the disadvantages of known optoelectronic devices.

### SUMMARY

In an embodiment, a device comprises at least one pixel assembly, the assembly comprising at least a first pixel generating an event-based data element and at least a second pixel generating a light intensity data element, each first and second pixel comprising a portion of a layer, said portion forming a photodiode, the device further comprising a first integrated circuit chip comprising a first substrate and a first interconnection network, and a second integrated circuit chip comprising a second substrate and a second interconnection network, the first and second integrated circuit chips being attached to each other by the first and second interconnection networks thereof, the layer being located on a first surface of the second substrate opposite to a second surface of the second substrate having the second interconnection network located thereon.

According to an embodiment, the device is an event-based camera.

According to an embodiment, the first integrated circuit chip comprises at least a portion of a control circuit of the at least first pixel and the second integrated circuit chip comprises the control circuit of the at least second pixel.

According to an embodiment, a portion of the control circuit of the at least first pixel is in the second integrated circuit chip.

According to an embodiment, the first and second integrated circuit chips are attached by molecular bonding.

According to an embodiment, the device comprises a plurality of assemblies of pixels arranged in an array.

According to an embodiment, each assembly comprises four second pixels surrounding a first pixel.

According to an embodiment, each assembly comprises eight second pixels surrounding a first pixel.

According to an embodiment, each assembly comprises three second pixels and one first pixel arranged in arrays.

According to an embodiment, the layer is continuous.

According to an embodiment, the layer fully covers the first surface of the second substrate.

According to an embodiment, the material of the layer is homogeneous.

According to an embodiment, the layer is in contact with the second substrate.

According to an embodiment, the layer is a layer of quantum dots or colloidal quantum dots.

According to an embodiment, the layer is made of a photosensitive perovskite material based on lead or on tin or a bulk heterojunction formed of photosensitive organic semiconductors.

### BRIEF DESCRIPTION OF THE DRAWINGS

The foregoing features and advantages, as well as others, will be described in detail in the rest of the disclosure of specific embodiments given by way of illustration and not limitation with reference to the accompanying drawings, in which:

FIG. 1 shows a cross-section view of an embodiment of an optoelectronic device;

FIG. 2 shows a perspective view of the embodiment of FIG. 1;

FIG. 3 shows an example of a pixel control circuit;

FIG. 4A shows an alternative arrangement of a pixel assembly; and

FIG. 4B shows another alternative arrangement of a pixel assembly.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the steps and elements that are useful for the understanding of the described embodiments have been illustrated and described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, when reference is made to terms qualifying absolute positions, such as terms “front”, “back”, “top”, “bottom”, “left”, “right”, etc., or relative positions, such as terms “above”, “under”, “upper”, “lower”, etc., or to terms qualifying directions, such as terms “horizontal”, “vertical”, etc., it is referred, unless specified otherwise, to the orientation of the drawings.

Unless specified otherwise, the expressions “about”, “approximately”, “substantially”, and “in the order of” signify plus or minus 10%, preferably of plus or minus 5%.

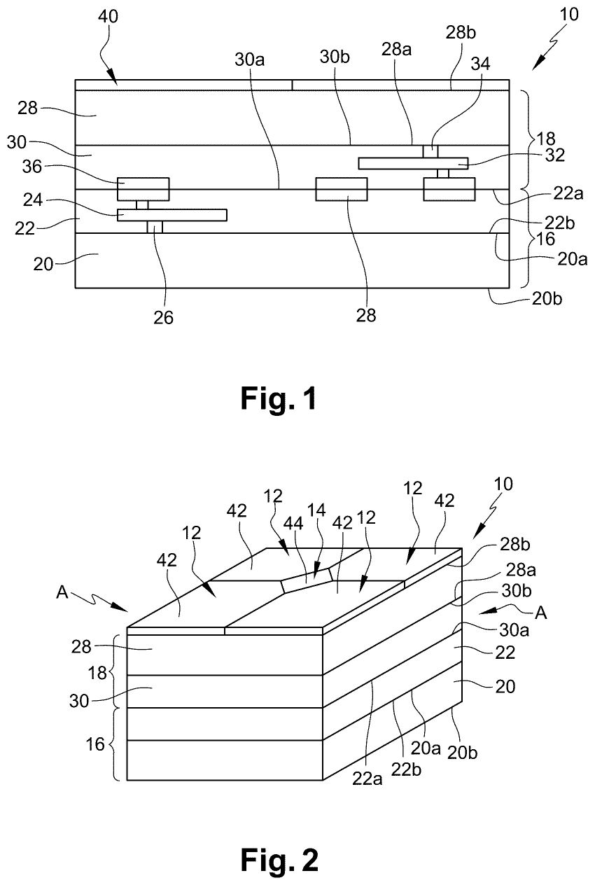

FIG. 1 shows a cross-section view of an embodiment of an optoelectronic device. FIG. 2 shows a perspective view of the embodiment of FIG. 1. More specifically, FIG. 1 shows a cross-section view along a plane A-A of the device of FIG. 2.

FIGS. 1 and 2 show an assembly 10 of pixels of the optoelectronic device. Assembly 10 corresponds, for example, to a portion of an image capture device, for example of a camera. Assembly 10 comprises at least one pixel 12 and at least one pixel 14. More specifically, assembly 10 comprises at least one event-based camera pixel 12 and at least one standard camera pixel 14. Pixel 14 is, for example, a pixel of “global shutter” type, or a pixel of “rolling shutter” type. Assembly 10 thus enables to obtain event-based data and standard brightness data. The camera is thus an event-based camera, or neuromorphic camera.

In the example of FIGS. 1 and 2, assembly 10 only comprises one pixel 14 and four pixels 12. Pixel 1 is surrounded by pixels 12. The device, that is, for example the camera, comprises a plurality of assemblies 10, preferably arranged in an array.

The device comprises a first integrated circuit chip 16 and a second integrated circuit chip 18. First integrated circuit chip 16 comprises a semiconductor substrate 20 and an interconnection network 22. Substrate 20 comprises an upper surface 20a and a lower surface 20b. Similarly, the interconnection network comprises an upper surface 22a and a lower surface 22b. Interconnection network 22 is bonded to substrate 20. More specifically, the lower surface 22b of interconnection network 22 is bonded to the upper surface 20a of substrate 20.

Substrate 20 is, for example, made of silicon. Electronic components, not shown in FIGS. 1 and 2, are formed inside and on top of substrate 20. For example, electronic components are formed on the upper surface of substrate 20.

Substrate 20 comprises at least a portion of the control circuit of pixel 14. In other words, at least part of the electronic components forming the control circuit of pixel 14 are located inside and on top of substrate 20. For example, the substrate comprises an amplifier, logic circuits, memory cells, and a readout circuit, synchronous or asynchronous, of pixel 14. Certain components may be common to a plurality of pixels.

Interconnection network 22 comprises a stack of insulating layers, metal tracks 24 located in the insulating layers, and conductive vias 26 located in the insulating layers and coupling together the conductive tracks. The lower layer of the stack of insulating layers is located in contact with substrate 20, and in particular with the upper surface of substrate 20. The upper layer of the stack, that is, the insulating layer of the interconnection network most distant from substrate 20, for example comprises metal tracks 28. Tracks 28 are flush with the upper surface 22a of the interconnection network.

Similarly, second integrated circuit chip 18 comprises a semiconductor substrate 28 and an interconnection network 30. Substrate 28 comprises an upper surface 28a and a lower surface 28b. Similarly, the interconnection network comprises an upper surface 30a and a lower surface 30b. Interconnection network 30 is bonded to substrate 28. More specifically, the lower surface 30b of interconnection network 30 is bonded to the upper surface 28a of substrate 28.

Substrate 28 is for example made of silicon. Electronic components, not shown in FIGS. 1 and 2, are formed inside and on top of substrate 28. For example, electronic components are formed on the upper surface of substrate 28.

Substrate 28 comprises, preferably entirely, the control circuits of pixels 12. In particular, substrate 28 preferably comprises the readout circuits of pixels 12. Substrate 28 for example comprises a portion of the control circuit of pixel 14.

Interconnection network 30 comprises a stack of insulating layers, metal tracks 32 located in the insulating layers, and conductive vias 34 located in the insulating layers and coupling together the conductive tracks. The lower layer of the stack of insulating layers is located in contact with substrate 28, and in particular with the upper surface of substrate 28. The upper layer of the stack, that is, the insulating layer of the interconnection network most distant from substrate 28, for example comprises metal tracks 36. Tracks 36 are flush with the upper surface 30a of the interconnection network.

Chips 16 and 18 are attached to each other. More specifically, networks 22 and 30 are attached to each other. More specifically, the upper surface 22a of network 22 and the upper surface 30a of network 30 are attached to each other. In the example of FIGS. 1 and 2, chips 16 and 18 are attached by molecular bonding. Thus, tracks 28 and 36 are placed so as to be in contact with one another. Alternatively, chips 16 and 18, more specifically the upper surfaces 22a and 30a, may be attached in another way, for example by solder balls, for example solder balls between tracks 28 and 36.

Chips 16 and 18 are thus electrically coupled. In other words, substrates 20 and 28 are electrically coupled by means of vias 26, of tracks 24, of tracks 28, of tracks 36, of tracks 32, and of vias 34.

Assembly 10 further comprises a layer 40. Layer 40 comprises, for example, quantum dots (QD). Layer 40 comprises, for example, colloidal quantum dots (CQD). Layer 40 may, alternatively, be made of photosensitive perovskites materials based on lead or on tin. In other words, layer 40 is, for example, made of a material having a formula of ABX₃ type, where element A is among the following elements: methylammonium, formamidinium, or cesium, where element B is among the following elements: lead or tin, and where element X is a halide, that is, an element among the following elements: iodine, chlorine, or bromine. The quantum dots of layer 40 may be made of perovskites, for example of photosensitive perovskites based on lead or on tin as previously described, or passivated with photosensitive perovskites based on lead or on tin. Layer 40 may also be a bulk heterojunction formed of photosensitive organic semiconductors such as PDPP3T and fullerenes. Layer 40 is located on chip 18, more specifically on substrate 28, more specifically on the lower surface 28b of substrate 28. Layer 40 is, for example, in contact with at least a portion of substrate 28. In other words, layer 40 and substrate 28 are not separated by an interconnection network.

Layer 40 is a continuous layer. Layer 40 preferably entirely covers surface 28b. In other words, layer 40 preferably comprises no opening exposing surface 28b. Layer 40 is common to the assembly of pixels 10. Preferably, layer 40 is common to all the pixels of the device.

Layer 40 comprises quantum dots. The quantum dots of layer 40 are, for example, located in a layer made of a material other than a semiconductor material, for example of an electrically-insulating material, for example of a resin.

By quantum dot, there is meant that each quantum dot forms a confinement area by quantum effect in all dimensions, that is, in the three dimensions of space. Each quantum dot thus preferably has dimensions, in all directions, in the order of a few tens of nanometers, in other words smaller than 100 nm, preferably in the range from 2 nm to 15 nm.

Each quantum dot comprises a core made of a semiconductor material, for example of lead sulfide. Said core preferably has dimensions in all directions in the order of some ten nanometers, in other words smaller than 100 nm. Each quantum dot further comprises ligands extending from the core. The ligands are preferably made of organic aliphatic molecules or metal-organic and inorganic molecules.

Due to their net charge and to their dipole moment, the ligands modify the effective doping of the quantum dot layers as well as their electronic affinity. For example, the ligands of the quantum dots of layer 40 may be molecules acting as N-type dopants, for example organic molecules such as thiolates.

Layer 40 forms photodiodes. In other words, layer 40 generates charges, in layer, when light rays at an operating wavelength of layer 40, depending on the quantum dots, are absorbed by layer 40.

The materials forming the quantum dots and the dimensions of each quantum dot, in particular the dimensions of the semiconductor core, determine the absorption wavelengths of the quantum dots, that is, the operating wavelengths of the photodiode. The operating wavelengths correspond, for example, to near infrared, that is, wavelengths in the range from 700 nm to 1.6 mm. The operating wavelengths may also correspond to medium infrared, that is, wavelengths in the range from 1.6 μm to 4 μm, or to the visible range, that is, wavelengths in the range from 300 nm to 700 nm.

It is possible to select an operating wavelength among a wavelength range larger than the wavelength range possible with a standard photodiode, that is, a photodiode comprising no quantum dot layer. Indeed, quantum dot layers correspond to an absorption curve having a peak significantly located on a wavelength, where said wavelength depends on the materials of the quantum dot and may be any wavelength in a wavelength range comprising at least the wavelengths from 300 nm to 4 μm.

For example, layer 40 comprises a single type of quantum dots. In other words, all the quantum dots of layer 40 have, for example, a core made of a same material and ligands made of the same material. Preferably, layer 40 is homogeneous. In other words, the composition of layer 40 is preferably identical all throughout layer 40.

Layer 40 comprises different regions 42, 44. Each pixel 14 comprises a region 44. Each pixel 12 comprises a region 42. Each region 42 is the portion of layer 40 generating charges for the corresponding pixel 12. Similarly, each region 14 is the portion of layer 40 generating charges for the corresponding pixel 14.

Each pixel comprises, for example, means for attracting the charges generated all throughout the region. For example, each pixel comprises a first layer for extracting electrons, referred to as an electrode, respectively holes, not shown, in contact with the lower surface of layer 40. Each pixel comprises, for example, a second layer for extracting holes, referred to as an electrode, respectively electrons, in contact with the upper surface of layer 40. The second extraction layer is transparent to the operating wavelengths of the pixel covered by said second layer. The first and second extraction layers are, for example, made of doped silicon, for example formed by doped regions of substrate 28 in the case of the first layer, or of a metal oxide, for example of TiOₓ, ZnO, AZO, IGZO, MoOₓ, CoO, CuOₓ NiOₓ. For example, each pixel comprises means for attracting charges towards the circuits located in the substrates 20 and 28 corresponding to said pixel.

Thus, during the operation of the device, charges are generated all throughout layer 40. The charges located in each region 42, 44 are attracted by said means towards the circuits corresponding to the pixel associated with regions 42, 44.

Regions 42 have, for example, the shape of a rectangle, preferably a square, having a tapered corner. The tapered corners of the four regions 42 face the same point, that is, the center of the assembly so that the portions of layer 40 located at the center of the assembly, between the tapered corners, form region 44. Thus, regions 42 comprise, in a same pixel row, two parallel sides, one being shorter than the other, the short sides being in contact with each other. Similarly, regions 42 comprise, in a same pixel column, that is, in the direction opposite to the row direction, two parallel sides, one being shorter than the other, the short sides being in contact with each other. Each region 42 further comprises a side coupling the shorter sides of said region 42, said side corresponding to a side of region 44. Region 44 thus is a quadrilateral in top view. Thus, region 44 is totally surrounded with regions 42.

Assemblies 10 are, for example, arranged in an array in the device. Preferably, each assembly 10 comprises pixels separate from the pixels of the other assemblies. Thus, each pixel 14 is, for example, separated from the pixel 14 of another assembly by pixels 12 of two assemblies 10.

In an operating mode of the device, the pixels may operate in non-simultaneous fashion, to be able to generate at different times the event-based and light intensity images. When only the event-based image is generated, only the event-based sensors operate, all charges then being collected by a charge extraction layer located in the corresponding pixels. This is allowed, among others, by the continuity of layer 40. This enables to increase the sensitivity and the speed of the event-based sensor, with no loss of spatial and spectral aliasing information.

In another operating mode, the event-based sensor is off and the charges photogenerated in the event-based pixels are distributed between the adjacent pixels.

In another operating mode, the two types of sensors may also be simultaneously operated, the electric field generated by each electrode allowing a charge collection with no electrical cross-talk between pixels.

FIG. 3 shows an example of a pixel control circuit. More specifically, FIG. 3 schematically shows a pixel 12 as well as a pixel 14.

Pixel 12 comprises a photodiode 50. Photodiode 50 corresponds to the portion 42 of layer 40 associated with said pixel 12. Photodiode 50 comprises a terminal, for example the cathode, coupled, preferably connected, for example via doped wells of the substrate 28 of chip 18, to a node of application of a bias voltage Vbias.

Pixel 12 further comprises a control circuit of pixel 12. The control circuit of pixel 12 comprises a control circuit 52 (RS/GS) of photodiode 50. Each photodiode 50, that is, each pixel 12, for example comprises circuit 52. Circuit 52 is located in substrate 28, preferably entirely in substrate 28. The pixel photodiode 50 is coupled, preferably connected, to circuit 52.

A circuit 54 is located in substrate 28. Circuit 54 is an analog-to-digital converter (ADC). Circuit 54 is preferably entirely in substrate 28. Circuit 54 is, for example, common to a plurality of pixels 12, for example common to all the pixels 12 of an assembly 10, for example only to the pixels 12 of an assembly 10. Circuit 54 is, for example, coupled, preferably connected, to circuit 52.

A circuit 56 is located in substrate 28. Circuit 56 is a pixel readout (RO) circuit, for example the readout circuit of assembly 10. Circuit 56 is preferably entirely in substrate 28. Circuit 56 is, for example, common to a plurality of pixels 12, for example common to all the pixels 12 of an assembly 10, for example only to the pixels 12 of an assembly 10. Circuit 56 is, for example, coupled, preferably connected, to circuit 54. Circuit 56 delivers, on an output 58, a value representative of the illumination of one or a plurality of pixels 12, for example pixels 12 of assembly 10.

Pixel 14 comprises a photodiode 60. Photodiode 60 corresponds to the portion 44 of layer 40 associated with said pixel 14. Photodiode 60 comprises a terminal, for example the cathode, coupled, preferably connected, for example via doped wells of the substrate 28 of chip 18, to a node of application of a bias voltage Vbias.

Pixel 14 comprises a control circuit of pixel 14. The control circuit of pixel 14 comprises, for example, a circuit (log) 62 having the function of applying a logarithm to the value obtained by photodiode 60. Circuit 62 is, for example, coupled, preferably connected, to the anode of photodiode 60. Circuit 62 is, for example, located, preferably entirely, in substrate 28.

Pixel 14 comprises a circuit (SF) 64. Circuit 64 is an amplifier, for example of common drain type, comprising for example a source-follower circuit. Circuit 64 is, for example, coupled, preferably connected, to circuit 62. Circuit 64 is, for example, located, preferably entirely, in substrate 28.

The control circuit of pixel 14 further comprises other components located in substrate 20. The control circuit of pixel 14 comprises, for example, comprises an amplifier (A) 66 coupled, preferably connected, to circuit 64. The control circuit of pixel 14 further comprises a logic circuit 68, for example a high-pass filter, associated with a memory 70. Circuit 68 is coupled, preferably connected, to amplifier 66, to receive as an input the signal amplified by amplifier 66. Memory circuit (MEM) 70 is configured to contain a value obtained by logic circuit 68.

Similarly, the control circuit of pixel 14 comprises another logic circuit 72, for example a high-pass filter, associated with a memory circuit (MEM) 74. Circuit 72 is coupled, preferably connected, to amplifier 66, to receive as an input the signal amplified by amplifier 66. Memory 74 is configured to contain a value obtained by logic circuit 72.

According to an embodiment, amplifier 66 is, for example, configured to be able to be reset, the resetting depending, for example, on the output values of circuits 68 and 72. For example, pixel 14 may comprise a logic circuit, not shown, for example an OR gate. Said logic circuit is, for example, in the first integrated circuit chip 16. Said logic circuit comprises, for example, an input coupled, preferably connected, to the output of circuit 68, another input coupled, preferably connected, to the output of circuit 72, and an output coupled, preferably connected, to an input of amplifier 66. For example, when this logic circuit (not explicitly shown) delivers a first binary value, the amplifier 66 is reset.

Pixel 14 further comprises a data processing circuit (DP) 76 and a readout circuit (RO) 78. Circuit 76 is, for example, coupled, preferably connected, to memories 70 and 74 and circuit 78 is, for example, coupled, preferably connected, to circuit 76. Circuits 76 and 78 are, for example, common to a plurality of pixels 14.

Thus, substrate 28 comprises the control circuit of pixels 12, preferably the entire control circuit of pixels 12. Substrate 20 preferably comprises no component of the control circuit of pixels 12. Substrate 20 comprises at least a portion of the control circuit of pixel 14. Substrate 28 may, for example, comprise a portion of the control circuit of pixel 14. The components of the control circuits located in the different substrates are coupled to one another by interconnection networks 22 and 30. In particular, the components of the control circuit of pixel 14 located on substrates 20 and 28 are coupled together by interconnection networks 22 and 30.

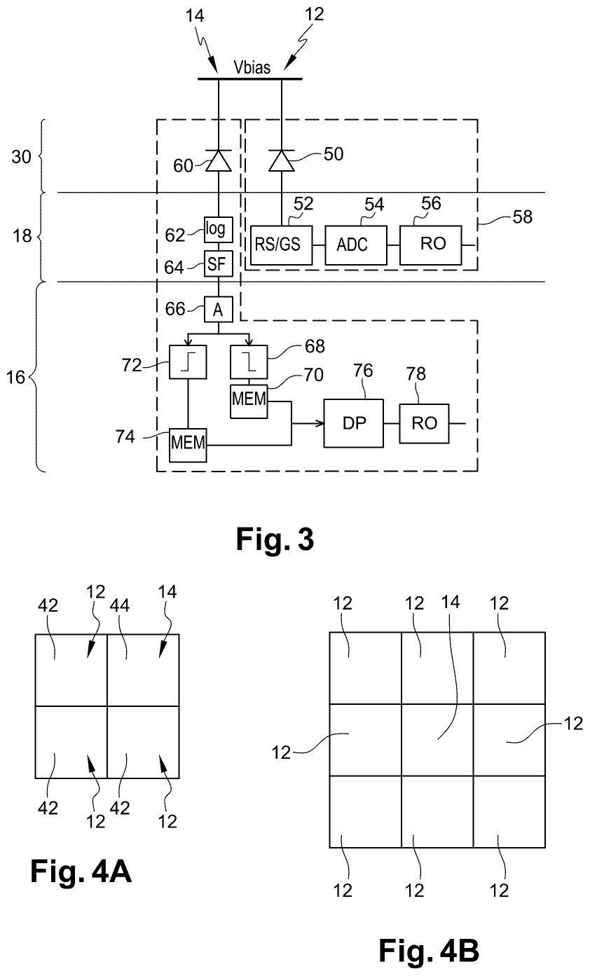

FIG. 4A shows an alternative arrangement of a pixel assembly. More specifically, FIG. 4A shows a top view of a layer 40 of an assembly of pixels 12 and 14 such as the assembly of FIGS. 1 and 2.

In the example of FIG. 4A, the pixel assembly comprises one pixel 14 and three pixels 12, the pixels being arranged in an array. The assembly thus comprises a column of two pixels 12 and a column comprising one pixel 14 and one pixel 12.

The pixel assembly is, for example, arranged in an array with other identical assemblies. Each pixel 14 is thus surrounded with pixels 12 of the assembly and of neighboring assemblies.

FIG. 4B shows another alternative arrangement of a pixel assembly. More specifically, FIG. 4B shows a top view of a layer 40 of an assembly of pixels 12 and 14 such as the assembly of FIGS. 1 and 2.

In the example of FIG. 4B, the pixel assembly comprises one pixel 14 and eight pixels 12, the pixels being arranged in an array. The assembly thus comprises two columns of three pixels 12 and one column comprising one pixel 14 and two pixels 12, in such a way that pixel 14 is surrounded by pixels 12.

The pixel assembly is, for example, arranged in an array with other identical assemblies. Each pixel 14 is thus separated from the neighboring pixels 14 by at least two pixels 12.

An advantage of the described embodiments is that the size of the pixels is not limited by the distance required by via manufacturing methods, as is the case in devices where the photodiode is coupled to the substrate by the interconnection network.

Another advantage of the described embodiments is that the control circuits, divided over a plurality of chips, enable to bring the pixels closer to one another.

Another advantage of the previously-described embodiments is that the device can deliver an event-based image and a light intensity image, for example non-simultaneously, the event-based and standard pixels being independently readable.

Another advantage of the described embodiments is that it is possible to form a full screen, by the use of a quantum dot layer. In other words, charges may be generated over the entire surface of the screen. There exists no area between pixels where charges cannot be generated.

Another advantage of the described embodiments is that the range of possible wavelengths is more significant, depending on the selection of the quantum dots.

Various embodiments and variants have been described. Those skilled in the art will understand that certain features of these various embodiments and variants may be combined, and other variants will occur to those skilled in the art.

Finally, the practical implementation of the described embodiments and variants is within the abilities of those skilled in the art based on the functional indications given hereabove.

1. A device, comprising:
an assembly of pixels, wherein the assembly of pixels comprises:
a first pixel configured to generate an event-based data element; and
a second pixel configured to generate a light intensity data element;
each first pixel and second pixel comprising a portion of a layer, said portion forming a photodiode;
a first integrated circuit chip comprising a first substrate and a first interconnection network;
a second integrated circuit chip comprising a second substrate and a second interconnection network;
wherein the first integrated circuit chip and the second integrated circuit chip are attached to each other by the first and second interconnection networks; and
wherein the layer is located on a first surface of the second substrate opposite to a second surface of the second substrate having the second interconnection network located thereon.

2. The device according to claim 1, wherein the device is an event-based camera.

3. The device according to claim 1:
wherein the first integrated circuit chip comprises at least a portion of a control circuit of the first pixel; and
wherein the second integrated circuit chip comprises a control circuit of the second pixel.

4. The device according to claim 3, wherein a further portion of the control circuit of the first pixel is in the second integrated circuit chip.

5. The device according to claim 1, wherein the first and second integrated circuit chips are attached at the first and second interconnection networks by molecular bonding.

6. The device according to claim 1, comprising a plurality of assemblies of pixels arranged in an array.

7. The device according to claim 6, wherein each assembly of pixels comprises four second pixels surrounding one first pixel.

8. The device according to claim 6, wherein each assembly of pixels comprises eight second pixels surrounding one first pixel.

9. The device according to claim 6, wherein each assembly of pixels comprises three second pixels and one first pixel arranged in an array.

10. The device according to claim 1, wherein the layer is continuous.

11. The device according to claim 1, wherein the layer entirely covers the first face of the second substrate.

12. The device according to claim 1, wherein a material of the layer is homogeneous.

13. The device according to claim 1, wherein the layer is in contact with the second substrate.

14. The device according to claim 1, wherein the layer is made of quantum dots.

15. The device according to claim 1, wherein the layer is made of colloidal quantum dots.

16. The device according to claim 1, wherein the layer is made of a photosensitive perovskite material based on one of lead or tin.

17. The device according to claim 1, wherein the layer is made of a bulk heterojunction formed of photosensitive organic semiconductors.
